(19) United States
(12) Patent Application Publication
(10) Pub. No.: US 2014/0046084 A1
(43) Pub. Date: Feb. 13, 2014

(54) Siloxane Compound and Cured Product Thereof

(71) Applicants: Hiroshi Honjo, Chiba-shi (JP); Toshihisa Ide, Eruma-gun (JP); Yoshinori Akamatsu, Matsusaka-shi (JP); Hiroshi Eguchi, Atlanta, GA (US); Junya Nakatsuji, Fujiminio-shi (JP); Makoto Matsuura, Ibaraki-shi (JP); Tsuyoshi Ogawa, Iruma-gun (JP); Kazuhiro Yamanaka, Tachikawa-shi (JP)

(72) Inventors: Hiroshi Honjo, Chiba-shi (JP); Toshihisa Ide, Eruma-gun (JP); Yoshinori Akamatsu, Matsusaka-shi (JP); Hiroshi Eguchi, Atlanta, GA (US); Junya Nakatsuji, Fujiminio-shi (JP); Makoto Matsuura, Ibaraki-shi (JP); Tsuyoshi Ogawa, Iruma-gun (JP); Kazuhiro Yamanaka, Tachikawa-shi (JP)

(73) Assignee: Central Glass Company, Limited, Ube-shi (JP)

(21) Appl. No.: 14/112,693

(22) PCT Filed: Apr. 17, 2012
(86) PCT No.: PCT/JP2012/060313

§ 371 Date: Oct. 18, 2013

(30) Foreign Application Priority Data
Apr. 20, 2011 (JP) 2011-094195
Apr. 12, 2012 (JP) 2012-090665

(51) Int. Cl. H01L 33/56; H01L 33/64

(52) U.S. Cl. CPC H01L 33/56; H01L 33/641
USPC 556/455

(57) ABSTRACT

A siloxane compound according to the present invention is represented by the general formula (1).

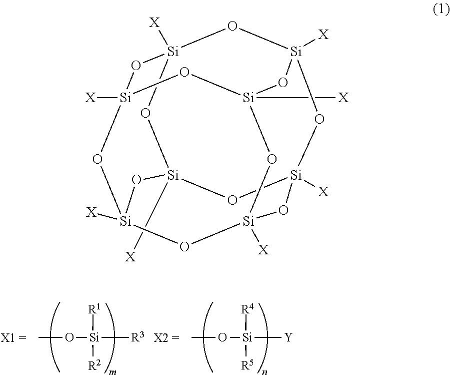

wherein X are each independently either X1 or X2 with the proviso that at least one of X is X2; R¹ to R⁵ are each independently a hydrogen atom, a C₁-C₈ alkyl, alkenyl or alkynyl group, a phenyl group or a pyridyl group; each of R¹ to R⁵ may have a carbon atom replaced by an oxygen atom and may have an ether bond, a carbonyl group or an ester bond in its structure; m and n are each independently an integer of 1 to 10; and Y are each independently a specific cross-linking group.

The siloxane compound according to the present invention has flowability and easy formability at lower temperatures as compared to conventional silsesquioxanes.

### TECHNICAL FIELD

The present invention relates to heat-resistant resins, and more particularly, to a siloxane compound and a cured product thereof. The cured product of the siloxane compound according to the present invention is usable as sealing materials and adhesives for semiconductors etc. where heat resistance is required and, when it is colorless and transparent, as optical sealing materials, lens materials, optical thin films, and the like.

### BACKGROUND ART

Sealing materials for semiconductors such as light emitting diodes (LED) are required to have sufficient heat resistance so as to resist heat generated during operation of the semiconductors.

Conventionally, heat-resistant epoxy or silicone resins have been used as semiconductor sealing materials. These conventional epoxy or silicon resin sealing materials are however higher in withstand voltage than silicon (Si) semiconductors and, when used for high-performance semiconductors typified by silicon carbide (SiC) power semiconductors, are not sufficient in heat resistance to resist high heat generated from the power semiconductors and thus tend to be thermally decomposed during operation of the semiconductors.

Polyimide resins are known as higher heat-resistant resins than the epoxy or silicon resins. Patent Document 1 discloses a surface protection film for a semiconductor element, which is formed by curing a polyimide precursor composition under heating at 230 to 300° C. However, the polyimide precursor composition is solid in a low-temperature range at around room temperature (20° C.) and thus is poor in formability.

Silsesquioxanes, which are one class of network-structured polysiloxanes formed by hydrolysis and condensation polymerization of alkyltrialkoxysilane etc., are known as other heat-resistant materials and are usable for various applications because the silsesquioxanes each have an inorganic siloxane structure to which organic functional groups are bonded and enable molecular design that takes advantage of the high heat resistance of the inorganic siloxane structure and the characteristics of the organic functional groups. Further, some of the silsesquioxanes are liquid at room temperature and can be used in potting processes in such a manner that the liquid silsesquioxanes are applied to substrate surfaces and cured by condensation polymerization under heating or ultraviolet irradiation. Patent Documents 2 to 5 and Non-Patent Documents 1 to 6 disclose synthesis methods of silsesquioxanes, respectively.

Various researches have been made on the use of silsesquioxanes, which combine heat resistance with formability, as sealing materials. However, there have not yet been obtained any silsesquioxane sealing materials that are insusceptible to deterioration even when heated under high-temperature conditions of 250° C. or higher over a few thousand hours. There are also problems that, although it is often the case to utilize hydrosilylation in the synthesis of silsesquioxanes that are liquid at room temperature and can be used in potting processes for sealing of semiconductors, the resulting silsesquioxanes may deteriorate in heat resistance due to the formation of alkylene chains such as propylene chain at the respective terminal ends of the silsesquioxanes by the hydrosilylation reaction (see Non-Patent Documents 5 and 6).

### PRIOR ART DOCUMENTS

### Patent Documents

Patent Document 1: Japanese Laid-Open Patent Publication No. 10-270611

Patent Document 2: Japanese Laid-Open Patent Publication No. 2004-143449

Patent Document 3: Japanese Laid-Open Patent Publication No. 2007-15991

Patent Document 4: Japanese Laid-Open Patent Publication No. 2009-191024

Patent Document 5: Japanese Laid-Open Patent Publication No. 2009-269820

### Non-Patent Documents

Non-Patent Document 1: I. Hasegawa et al., Chem. Lett., pp. 1319 (1988)

Non-Patent Document 2: V. Sudarsanan et al., J. Org. Chem., pp. 1892 (2007)

Non-Patent Document 3: M. A. Esteruelas et al., Organometallics, pp. 3891 (2004)

Non-Patent Document 4: A. Mori et al., Chem. Lett., pp. 107 (1995)

Non-Patent Document 5: J. Mater. Chem., 2007, 17, pp. 3575-3580

Non-Patent Document 6: Proc. of SPIE Vol. 6517 651729-0

### SUMMARY OF THE INVENTION

### Problems to be Solved by the Invention

It is an object of the present invention to provide a siloxane compound that has flowability and easy formability at lower temperatures as compared to conventional silsesquioxanes.

### Means for Solving the Problems

The present inventors have found that a siloxane compound in which a specific cross-linking group is bonded to a specific siloxane skeleton is liquid at 60° C. or lower and curable by heating at 150 to 350° C. and thus shows good formability even under relatively low-temperature conditions. The present invention is based on this finding.

Namely, the present invention includes the following aspects.

[Inventive Aspect 1]

A siloxane compound of the general formula (1):

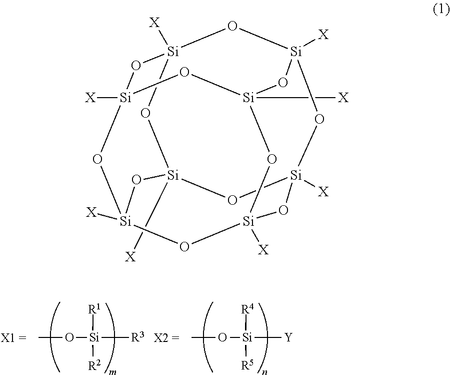

where X are each independently either X1 or X2 with the proviso that at least one of X is X2; R¹ to R⁵ are each independently a hydrogen atom, a C₁-C₈ alkyl, alkenyl or alkynyl group, a phenyl group or a pyridyl group; each of R¹ to R⁵ may have a carbon atom replaced by an oxygen atom and may have an ether bond, a carbonyl group or an ester bond in its structure; m and n are each independently an integer of 1 to 10; and Y are each independently at least one cross-linking group selected from the group consisting of those of the structural formulas (2) to (12):

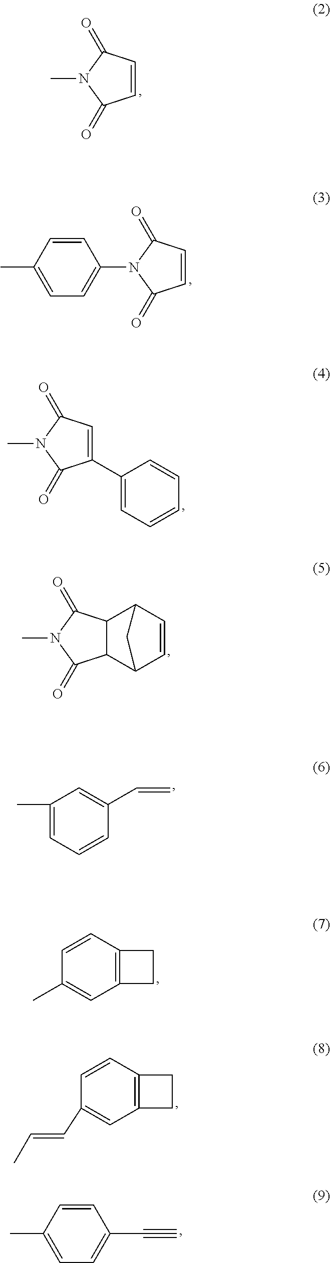

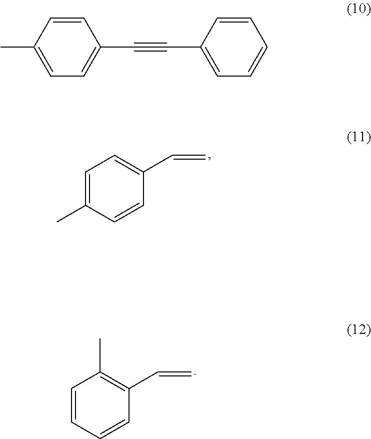

[Inventive Aspect 2]

The siloxane compound according to Inventive Aspect 1, wherein all of R¹ to R⁵ are methyl, m is an integer of 1 to 3 and n is an integer of 2 to 3.

[Inventive Aspect 3]

A cured product obtained by reaction of the cross-linking group of the siloxane compound according to Inventive Aspect 1 or 2.

[Inventive Aspect 4]

A sealing material containing the cured product according to Inventive Aspect 3.

The siloxane compound according to the present invention is liquid at 60° C. or lower and can suitably be used in forming processes, application processes or potting processes. When the viscosity of the siloxane compound is adjusted with the addition of any other component, it becomes easier to use the siloxane compound in forming processes, application processes or potting processes. Further, the siloxane compound according to the present invention is formed into a cured product with high heat resistance by cross-linking reaction of the cross-linking groups of the respective siloxane molecules when the siloxane compound is heated solely or in the form of a composition with any other component.

### DETAILED DESCRIPTION OF THE EMBODIMENTS

Hereinafter, the siloxane compound according to the present invention and its synthesis method, features and application for use as semiconductor sealing materials will be sequentially described below.

1. Siloxane Compound

The siloxane compound according to the present invention is represented by the general formula (1). In the following description, the siloxane compound of the general formula (1) is sometimes simply referred to as “siloxane compound (1)”.

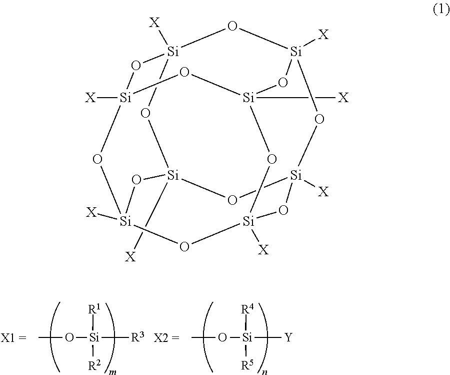

In the general formula (1), X are each independently either X1 or X2 with the proviso that at least one of X is X2; R¹ to R⁵ are each independently a hydrogen atom, a C₁-C₈ alkyl, alkenyl or alkynyl group, a phenyl group or a pyridyl group; each of R¹ to R⁵ may have a carbon atom replaced by an oxygen atom and may have an ether bond, a carbonyl group or an ester bond in its structure; m and n are each independently an integer of 1 to 10; and Y are each independently a cross-linking group.

Examples of the C₁-C₈ alkyl group are methyl, ethyl, 1-propyl, 2-propyl, n-butyl and sec-butyl. As the alkyl group, methyl is preferred for the reason that the siloxane compound (1) with a methyl group is easy to synthesize.

Examples of the C₁-C₈ alkenyl group are vinyl, allyl, methacryloyl, acryloyl, styrenyl and norbornanyl. As the alkenyl group, vinyl or methacryloyl is preferred for the reason that the siloxane compound (1) with a vinyl group or methacryloyl group is easy to synthesize.

Examples of the C₁-C₈ alkynyl group are ethynyl and phenylethynyl. As the alkynyl group, phenylethynyl is preferred for the reason that the siloxane compound (1) with a phenylethynyl group is easy to synthesize.

For the same reasons as above, it is preferable that: the phenyl group is a normal phenyl group of 6 carbon atoms; and the pyridyl group is a normal pyridyl group of 5 carbon atoms. The phenyl group and the pyridyl group are preferably unsubstituted although the phenyl group and the pyridyl group may have substituents.

For viscosity adjustment, any carbon atom of the alkyl, alkenyl, alkynyl, phenyl or pyridyl group may be replaced by an oxygen atom to form an ether bond, a carbonyl group or an ester bond in the molecular structure. The above functional bond or group is effective in adjusting the viscosity of the siloxane compound (1).

In the siloxane compound (1), the cross-linking group Y are each independently at least one selected from the group consisting of cross-linking groups of the structural formulas (2) to (12).

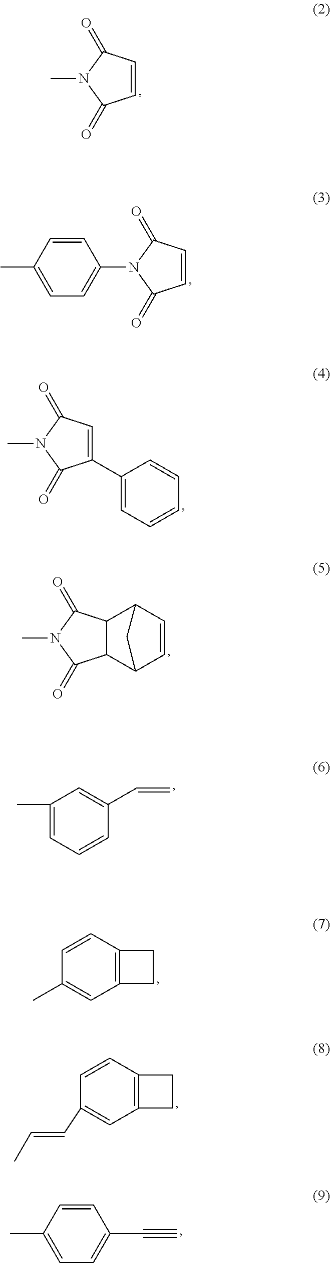

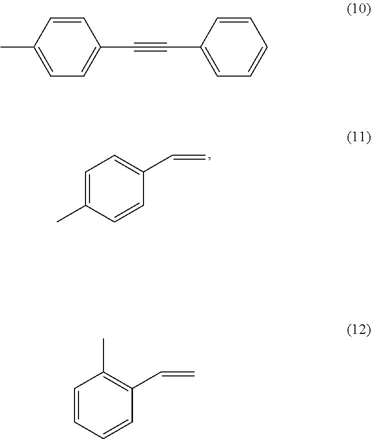

The cross-linking groups of the structural formulas (2) to (12) have heat resistance because of their ring structures and thus do not cause deterioration in the heat resistance of the siloxane compound (1). Further, the cross-linking groups of the structural formulas (2) to (12) each have a double bond or triple bond and allow easy linkage. When the siloxane compound (1) has at least two X2, preferably three or more X2, the siloxane compound (1) can be easily and efficiently formed into a cured product by cross-linking reaction of the cross-linking groups Y of the respective siloxane molecules under heating.

Namely, it is possible to obtain the siloxane compound (1) by bonding of the cross-linking group Y of the structural formulas (2) to (12) to X2 and possible to obtain the cured product of the siloxane compound (1) with very high heat resistance by cross-linking reaction of the cross-linking groups Y of the respective siloxane molecules under heating.

In particular, the siloxane compound (1) can be easily obtained as a single composition by organic synthesis in the case where, in the general formula (1), X are either X1 or X2 with the proviso that at least one of X is X2, all of R¹ to R⁵ are methyl; m is an integer of 1 to 3; n is an integer of 2 to 3; and Y are any of the above cross-linking groups. This siloxane compound (1) is liquid in a temperature range from room temperature (20° C.) to 60° C. and thus is suitable for use in semiconductor sealing materials.

2. Synthesis of Siloxane Compound (1)

2-1. Synthesis of Siloxane Precursor (A)

A precursor (A) of the siloxane compound (1) (hereinafter sometimes simply referred to as “siloxane precursor (A)”), which has a cage skeleton formed of 8 silicon atoms and 12 oxygen atoms by siloxane bonding: —Si—O—, is first synthesized.

More specifically, the siloxane precursor (A) is synthesized in the form of an ammonium salt by adding a tetraalkoxysilane such as tetraethoxysilane into an aqueous solution of quaternary ammonium hydroxide, and then, stirring the resulting solution at room temperature as indicated in the following reaction scheme. In this reaction, the siloxane precursor (A) is selectively formed with a cage skeleton by siloxane bonding: —Si—O— of 8 silicon atoms and 12 oxygen atoms (see Non-Patent Document 1).

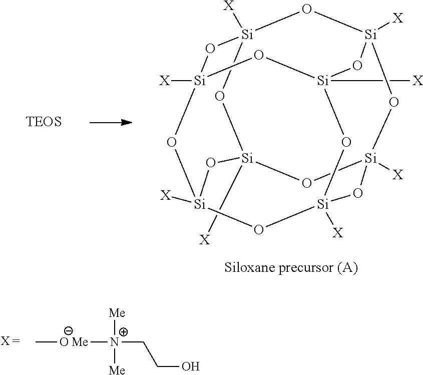

Specific examples of the quaternary ammonium hydroxide are tetramethylammonium, tetraethylammonium, tetrapropylammonium, tetrabutylammonium and choline. Among others, choline is preferred for the reasons that choline can be obtained in solid form and shows high solubility in an alcohol used as a reaction solvent in the subsequent step.

2.2 Silylation of Siloxane Precursor (A)

The siloxane precursor (A) is next silylated by reaction with a halogenated dialkylsilane such as chlorodimethylsilane (see Non-Patent Document 1) or a disiloxane such as hexamethyl disiloxane (see Patent Document 5).

More specifically, the silylation of the siloxane precursor (A) is conducted by reacting the above-obtained ammonium salt such as choline salt with e.g. chlorodimethylsilane in the presence of an organic base in an alcohol solvent, thereby forming a siloxane precursor (B), as indicated in the following reaction scheme.

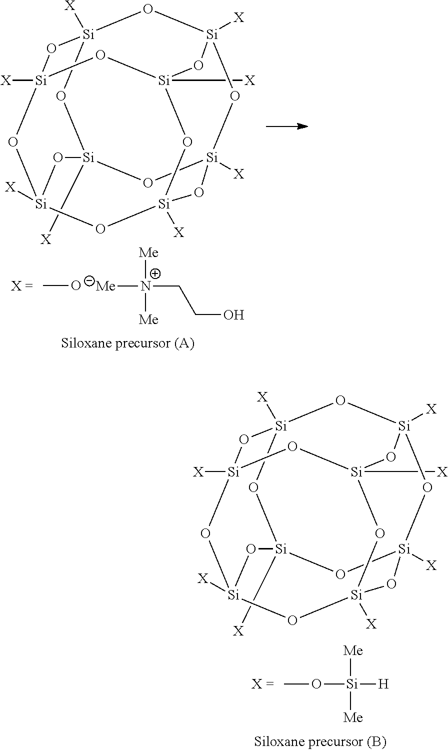

Suitable examples of the alcohol used as the reaction solvent are methanol, ethanol and 2-propanol. Suitable examples of the organic base are triethylamine and pyridine.

2.3 Chlorination of Siloxane Precursor (B)

Then, the siloxane precursor (B) is chlorinated by reaction with trichloroisocyanuric acid (see Non-Patent Document 2), hexachlorocyclohexane in the presence of a rhodium catalyst (see Non-Patent Document 3) or chlorine gas etc. Although it is feasible to conduct the chlorination of the siloxane precursor (B) by any chlorination technique as disclosed in known publications (e.g. S. Varaprath et al., Journal of Organic Chemistry, Vol. 692, pp. 1892-1897 etc.), the siloxane precursor (B) is preferably chlorinated by reaction with trichloroisocyanuric acid or chlorine gas in terms of less by-product and practical cost efficiency.

More specifically, the chlorination of the siloxane precursor (B) is conducted by reacting the siloxane precursor (B) with e.g. trichloroisocyanuric acid in an organic solvent, thereby forming a siloxane precursor (C), as indicated in the following reaction scheme.

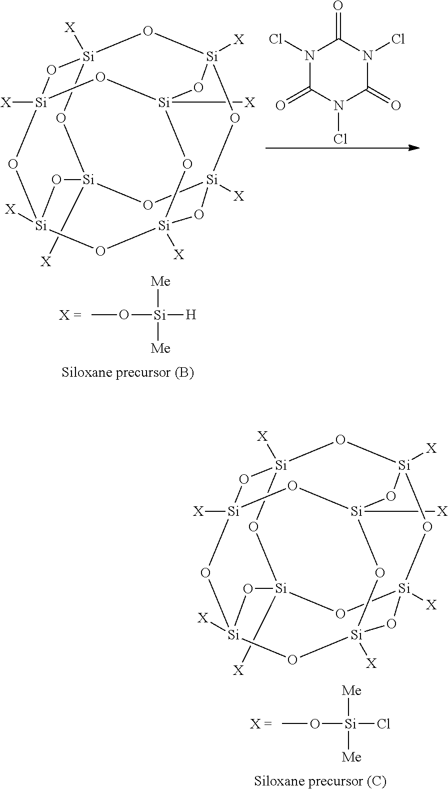

Suitable examples of the organic solvent are: chlorinated solvents such as dichloromethane, chloroform and dichloroethane; and tetrahydrofuran.

2.4 Synthesis of Siloxane Compound (1)

The siloxane compound (1) is obtained by adding the cross-linking agent Y of the structural formulas (2) to (12) to the siloxane precursor (C).

For example, the following silanolate compounds, each of which has a cross-linking group of the structural formula (7), that is, a benzocyclobutenyl group, can be obtained as the silicon compound (1) by reacting 4-bromobenzocyclobutene with an organic metal reagent and reacting the resulting metal-halogen exchange product with the siloxane precursor (C). It is herein noted that the present invention is not limited to those silanolate compounds.

Synthesis examples of benzocyclobutenyl-containing silanolate compounds will be explained in more detail below.

First, a benzocyclobutenyl lithium salt is formed by reaction of 4-bromobenzocyclobutene with alkyl lithium salt such as n-butyl lithium, tert-butyl lithium or methyl lithium as indicated in the following scheme (see Non-Patent Document 5).

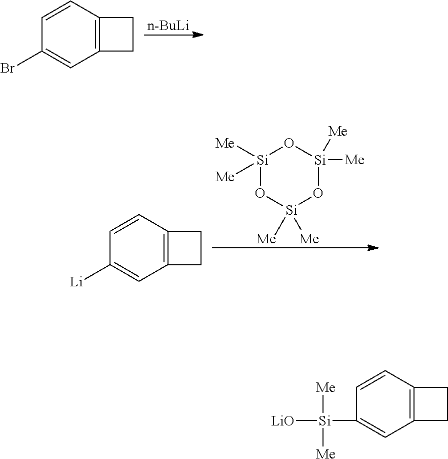

As the organic metal reagent, n-butyl lithium is preferably used in terms of availability. The benzocyclobutenyl lithium salt is then reacted with hexamethylcyclotrisiloxane. A benzocyclobutenyl-containing siloxlithium compound is obtained through ring-cleavage reaction of the hexamethylcyclotrisiloxane.

By the same operation as above, siloxylithium compounds (A) to (E) can be synthesized from bromo compounds (a) to (e) through the following reaction routes, respectively.

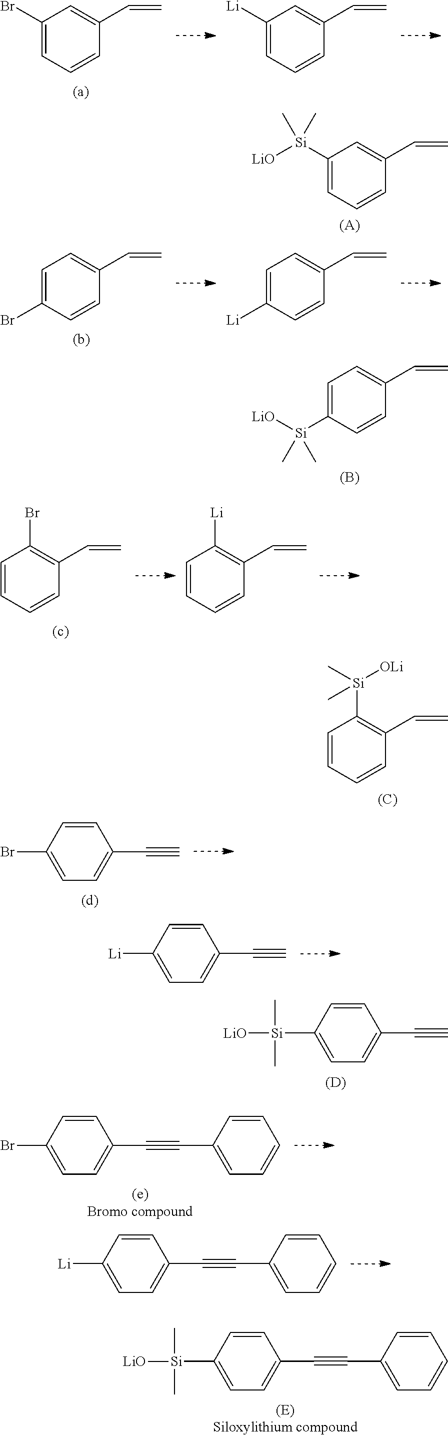

A silanolate compound having has a benzocyclobutenyl group of the structural formula (7) is synthesized as one example of the siloxane compound (1) by reaction of the siloxane precursor (C) and the benzocyclobutenyl-containing siloxlithium compound as indicated in the following reaction scheme.

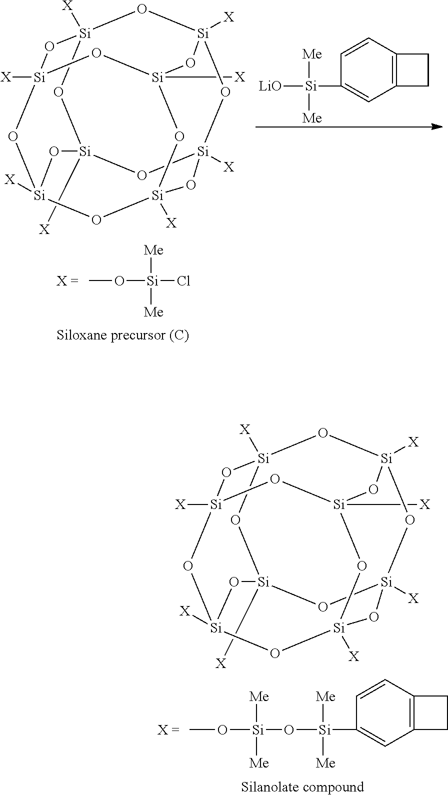

The siloxylithium compounds (A) to (E) can be converted to corresponding silanolate compounds (AA) to (EE) through chemical reactions by the same operation as above.

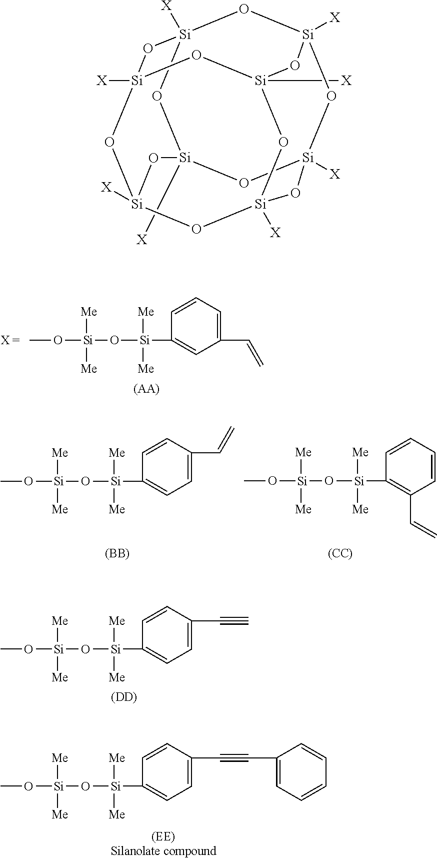

3. Use of Siloxane Compound (1) as Semiconductor Sealing Material

A sealing material for semiconductors is required to have strong adhesion to a metal wiring material over a wide temperature range. It is thus necessary to adjust the linear expansion coefficient of the sealing material in such a manner that the linear expansion coefficient of the sealing material becomes as close as that of the metal wiring material. There are a plurality of conceivable ways to cope with this requirement for use of the siloxane compound (1) as the sealing material.

One conceivable way is to mix the siloxane compound (1) with an inorganic filler. The linear expansion coefficient of the siloxane compound (1) can be adjusted to an arbitrary value by mixing the siloxane compound (1) with the inorganic filler such as silica or alumina. In the present invention, the siloxane compound (1) is liquid in a temperature range up to 60° C. and thus is easily mixable with the inorganic filler.

Another conceivable way is to utilize thermal addition polymerization. There arises a problem of bubble and volume contraction in the case of utilizing hydrolysis/dehydration-condensation of silicon alkoxide, typified by sol-gel reaction, as the final curing reaction in a polymerization process. Thus, thermal addition polymerization of the cross-linking group is utilized as the final curing reaction in the present invention. This thermal addition polymerization is considered as the suitable curing reaction system of the sealing material due to the fact that there is no need to use ultraviolet irradiation and curing catalyst in the thermal addition polymerization. Further, the cross-linking group Y is considered as the most preferable addition polymerization/cross-linking group due to the facts that: the cross-linking group Y goes through curing reaction at 350° C. or lower, i.e., in the heat resistant temperature range of power semiconductor materials; and the resulting cured product shows very high durability such as mass reduction rate of 10 mass % or lower in long-term heat resistance test at 250° C.

### EXAMPLES

The present invention will be described in more detail below with reference to the following examples. It should be understood that the following examples are illustrative and are not intended to limit the present invention thereto. Herein, samples of siloxane compounds (1) obtained in the respective examples, siloxane compounds obtained in the respective comparative examples and falling out of the scope of the present invention and cured products of the siloxane compounds (1) and the comparative siloxane compounds were tested for their physical properties by the following methods.

[Test Methods]

<Measurement of Viscosity>

The viscosity of the siloxane sample was measured at 25° C. with the use of a rotating viscometer (product name “DV-II+PRO” manufactured by Brookfield Engineering Inc.) and a temperature control unit (product name “THERMOSEL” manufactured by Brookfield Engineering Inc.).

<Measurement of 5 Mass % Reduction Temperature>

Using a thermal mass-differential thermal analyzer (product name “TG8120” manufactured by Rigaku Corporation), the cured siloxane sample was heated from 30° C. at a temperature rise rate of 5° C./min under the flow of air at 50 ml/min. The temperature at which the mass of the cured siloxane sample was reduced by 5 mass % relative to that before the measurement was determined as 5 mass % reduction temperature.

<Measurement of 300° C., 350° C. or 400° C. Mass Reduction Rate>

Using the same thermal mass-differential thermal analyzer as above, the cured siloxane sample was kept at 300° C., 350° C. or 400° C. for 2 hours under the flow of nitrogen at 50 ml/min. The rate of reduction of the mass of the cured siloxane sample at the respective temperature relative to that before the measurement was determined as 300° C., 350° C. or 400° C. mass reduction rate.

<Measurement of Glass Transition Temperature>

The glass transition temperature of the cured siloxane sample was measured by heating the cured siloxane sample from 30° C. to 300° C. at a temperature rise rate of 5° C./min under the application of a 10-g load with the use of a thermomechanical analyzer (product name “TMA8310” manufactured by Rigaku Corporation).

1. Synthesis of Siloxane Precursors (A) and (B)

Siloxane precursors (A) and (B) were synthesized as follows in Synthesis Examples 1 to 4.

### Synthesis Example 1

### Synthesis of Siloxane Precursor (A)

Into a 1-L three-neck flask with a thermometer and a reflux condenser, 200 g (960 mmol) of tetraethoxysilane and 233 g (960 mmol) of 50 mass % aqueous choline hydroxide solution were placed. The resulting solution was stirred for 12 hours at room temperature. After the completion of the stirring, 100 g of 2-propanol was added to the solution. The solution was further stirred for 30 minutes and then cooled to 3° C. so as to thereby precipitate a crude product out of the solution. The precipitated crude product was filtered out, washed with 2-propanol and dried. There was thus obtained 151 g of octa(2-hydroxyethyltrimethylammonium)silsesquioxane-36 hydrate in white powder form as the siloxane precursor (A). The reaction yield was 62 mass %. The structure of octa(2-hydroxyethyltrimethylammonium)silsesquioxane is indicated below.

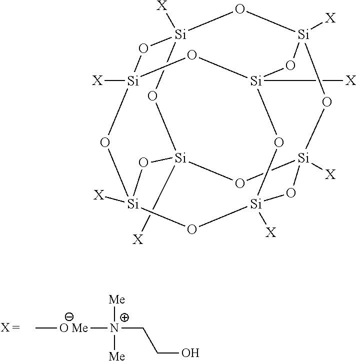

### Synthesis Example 2

### Conversion of Siloxane Precursor (A) to Siloxane Precursor (B)

Into a 1-L three-neck flask with a thermometer and a reflux condenser, 100 g of 2-propanol, 1910 g (20.2 mol) of dimethylchlorosilane and 390 g (4.93 mol) of pyridine were placed. Further, 100 g (4.93 mol) of octa(2-hydroxyethyltrimethylammonium)silsesquioxane-36 hydrate obtained in Synthesis Example 1 was added into the flask. The resulting solution was stirred for 12 hours at room temperature. After the completion of the stirring, the solution was distilled by an evaporator. The distillate from the evaporator was removed, whereas the bottom product of the evaporator was dropped into 300 g of toluene and washed three times with 300 g of ion exchanged water. The thus-obtained organic layer was dried with 30 g of magnesium sulfate. After the magnesium sulfate was filtered out of the organic layer, the organic layer was concentrated under a reduced pressure so as to precipitate a crude product. The crude product was then washed with methanol and dried. There was thus yielded 46.0 g of octa(hydrodimethylsiloxy)silsesquioxane in white powder form as the siloxane precursor (B). The reaction yield of was 91.6 mass %. The structure of yield of octa(hydrodimethylsiloxy)silsesquioxane is indicated below.

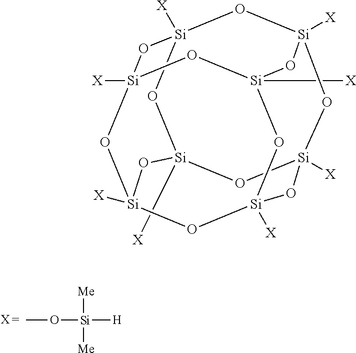

### Synthesis Example 3

### Conversion of Siloxane Precursor (A) to Siloxane Precursor (B)

The same operation as that of Synthesis Example 2 was performed except that: the amount of dimethylchlorosilane used was changed to 860 g (9.09 mol); and 1096 g (9.09 mol) of vinyldimethylchlorosilane was used in combination with the dimethylchlorosilane. There was thus yielded 51.0 g of tetra(hydrodimethylsiloxy)tetra(vinyldimethylsiloxy)silsesquioxane as the siloxane precursor (B). The reaction yield was 85 mass %. The structure of tetra(hydrodimethylsiloxy)tetra(vinyldimethylsiloxy)silsesquioxane is indicated below.

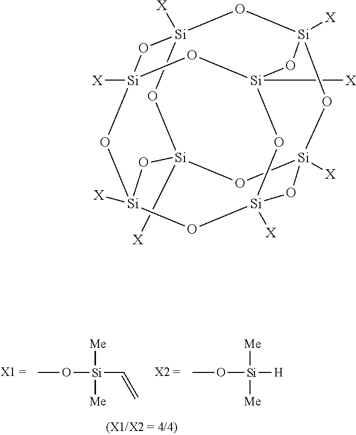

### Synthesis Example 4

### Conversion of Siloxane Precursor (A) to Siloxane Precursor (B)

The same operation as that of Synthesis Example 2 was performed except that: the amount of dimethylchlorosilane used was changed to 860 g (9.09 mol); and 988 g (9.09 mol) of trimethylchlorosilane was used in combination with the dimethylchlorosilane. There was thus yielded 46.4 g of tetra(hydrodimethylsiloxy)tetra(trimethylsiloxy)silsesquioxane as the siloxane precursor (B). The reaction yield was 83.0 mass %. The structure of tetra(hydrodimethylsiloxy)tetra(trimethylsiloxy)silsesquioxane is indicated below.

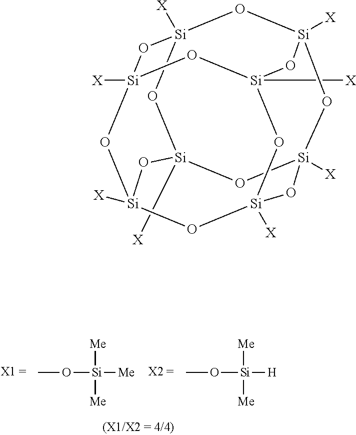

2. Synthesis of Siloxane Compound (1)

The siloxane precursors (B) obtained in Synthesis Examples 2 to 4 were chlorinated to siloxane precursors (C) and then converted to siloxane compounds (A) to (D) as the siloxane compound (1), respectively. The detailed synthesis procedures will be explained below.

### Example 1

### Siloxane Compound (A)

Into a 300-mL three-neck flask with a thermometer and a reflux condenser, 50.0 g of tetrahydrofuran and 10.2 g (10.0 mmol) of the octa(hydrodimethylsiloxy)silsesquioxane obtained in Synthesis Example 2 were placed. The resulting solution inside the flask was cooled to −78° C. while stirring. After the inside temperature of the flask reached −78° C., 6.28 g (27.0 mmol) of trichloroisocyanuric acid was added to the solution. After the completion of the adding, the solution was further stirred at −78° C. for 30 minutes. The solution was raised to room temperature while stirring. The tetrahydrofuran solution was obtained upon filtering out any insoluble deposit.

Subsequently, 14.6 g (80.0 mmol) of 4-bromobenzocyclobutene and 50 g of diethyl ether were placed into a 1-L three-neck flask with a thermometer and a reflux condenser. The resulting solution inside the flask was cooled to −78° C. while stirring. After the inside temperature of the flask reached −78° C., 56 ml (90 mmol) of 1.6 mol/L solution of butyl lithium in hexane was dropped into the solution over 30 minutes. After the completion of the dropping, the solution was further stirred for 30 minutes. Then, 5.94 g (26.7 mmol) of hexamethylcyclotrisiloxane was added to the solution. The solution was raised to room temperature while stirring. The solution was further stirred for 12 hours at room temperature.

The thus-obtained solution inside the flask was cooled to 3° C. After the inside temperature of the flask reached 3° C., the above tetrahydrofuran solution was dropped into the cooled solution over 10 minutes. After the completion of the dropping, the mixed solution was raised to room temperature while stirring. The mixed solution was kept stirred for 2 hours at room temperature. After the completion of the stirring, the mixed solution was admixed with 50 g of diisopropyl ether and 50 g of pure water and separated into two phases by stirring for 30 minutes. The aqueous phase was separated from the organic phase. The organic phase was then washed three times with 50 g of distilled water and dried with 10 g of magnesium sulfate. After the removal of the magnesium sulfate, the organic phase was concentrated under a reduced pressure at 150° C./0.1 mmHg. By this, the siloxane compound of the general formula (1) where X1=0 (number, the same applies to the following); X2=8 (number, the same applies to the following); R⁴, R⁵═CH₃; Y=cross-linking group of the structural formula (7); m=0; and n=2 (hereinafter referred to as “siloxane compound (A)”) was obtained in colorless transparent oily form in an amount of 19.9 g and at a yield of 82%. The viscosity of this oily compound was determined to be 1700 mPa·s by viscosity measurement.

The structure of the siloxane compound (A) is indicated below.

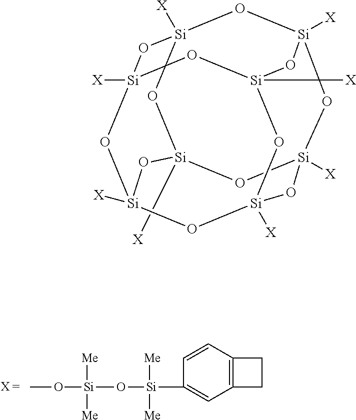

Further, the nuclear magnetic resonance (NMR) signals of the siloxane compound (A) and the molecular weight measurement result of the siloxane compound (A) by gel permeation chromatography (GPC) are indicated below.

¹H NMR (solvent: deutrated chloroform, reference material: tetramethylsilane); δ 0.07 (s, 6H), 0.30 (s, 6H), 0.70 (s, 6H), 3.14 (s, 4H), 7.01 (d, J=6.59 Hz, 1H), 7.20 (s, 1H), 7.36 (d, J=6.59 Hz, 1H).

²⁹Si NMR (solvent: deutrated chloroform, reference material: tetramethylsilane); δ −1.1, −17.7, −110.0.

GPC (in terms of polystyrene, RI detector) Mw=2530, Mw/Mn=1.1.

The siloxane compound (A) was poured into a mold of silicon (product name “Shin-Etsu Silicon SH9555” manufactured by Shin-Etsu Chemical Co., Ltd.) and subjected to cross-linking reaction by heating at atmospheric pressure and at 250° C. for 1 hour, thereby forming a cured product of 2 mm thickness with no bubble and cracking. The 5 mass % reduction temperature of the cured product was 460° C. The linear expansion coefficient of the cured product was 140 ppm/° C. The cured product had no glass transition temperature observed in the range of 30 to 300° C.

### Example 2

### Siloxane Compound (B)

The synthesis was performed in the same manner as in Example 1 using the tetra(hydrodimethylsiloxy)tetra(trimethylsiloxy)silsesquioxane obtained in Synthesis Example 4. As a result, the silicon compound of the general formula (1) where X1=4; X2=4; R¹, R², R³, R⁴, R⁵═CH₃; and Y=cross-linking group of the structural formula (7) (hereinafter referred to as “siloxane compound (B)”) was obtained in oily form in an amount of 32.2 g and at a yield of 91 mass %. The viscosity of this oily compound was determined to be 1100 mPa·s by viscosity measurement.

The structure of the siloxane compound (B) is indicated below.

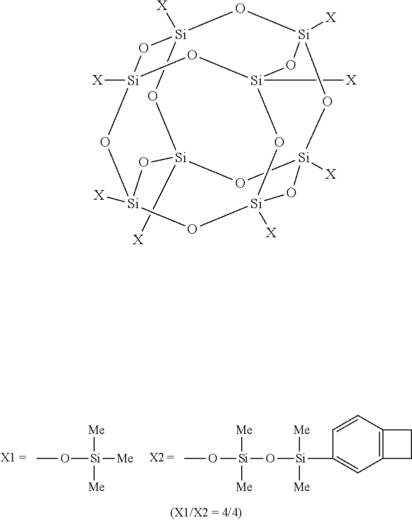

Further, the NMR and GPC measurement results of the siloxane compound (B) are indicated below.

¹H NMR (solvent: deutrated chloroform, reference material: tetramethylsilane); δ 0.05-0.13 (m, 15H), 0.28-0.32 (m, 6H), 3.14 (s, 4H), 7.02-7.03 (m, 1H), 7.19-7.21 (m, 1H), 7.36-7.39 (m, 1H).

²⁹Si NMR (solvent: deutrated chloroform, reference material: tetramethylsilane); δ 12.7, −1.1, −17.8, −108.9, −110.0.

GPC (in terms of polystyrene, RI detector) Mw=1990, Mw/Mn=1.1.

The siloxane compound (B) was poured into a mold of silicon (product name “Shin-Etsu Silicon SH9555” manufactured by Shin-Etsu Chemical Co., Ltd.) and subjected to cross-linking reaction by heating at atmospheric pressure and at 250° C. for 1 hour, thereby forming a cured product of 2 mm thickness with no bubble and cracking. The 5 mass % reduction temperature of the cured product was 480° C.

### Example 3

### Siloxane Compound (C)

The synthesis was performed in the same manner as in Example 1 using 22.4 g (20.0 mmol) of the tetra(hydrodimethylsiloxy)tetra(vinyldimethylsiloxy)silsesquioxane obtained in Synthesis Example 3. As a result, the siloxane compound of the general formula (1) where X1=4; X2=4; R¹, R², R³, R⁴, R⁵=vinyl; and Y=cross-linking group of the structural formula (7) (hereinafter referred to as “siloxane compound (C)”) was obtained in oily form in an amount of 32.9 g and at a yield of 90%. The viscosity of this oily compound was 900 mPa·s.

The structure of the siloxane compound (C) is indicated below.

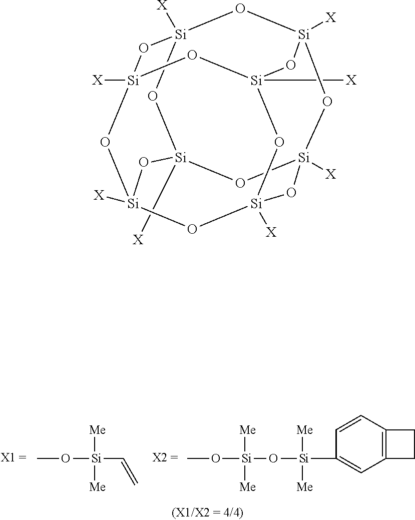

Further, the NMR measurement results of the siloxane compound (C) are indicated below.

¹H NMR (solvent: deutrated chloroform, reference material: tetramethylsilane); δ 0.05-0.07 (m, 6H), 0.13-0.15 (m, 6H), 0.28-0.31 (m, 6H), 3.15 (s, 4H), 5.75-5.78 (m, 1H), 5.88-5.93 (m, 1H), 6.04-6.07 (m, 1H), 7.01-7.03 (m, 1H), 7.20-7.22 (m, 1H), 7.36-7.38 (m, 1H).

The siloxane compound (C) was poured into a mold of silicon (product name “Shin-Etsu Silicon SH9555” manufactured by Shin-Etsu Chemical Co., Ltd.) and subjected to cross-linking reaction by heating at atmospheric pressure and at 250° C. for 1 hour, thereby forming a cured product of 2 mm thickness with no bubble and cracking. The 5 mass % reduction temperature of the cured product was 460° C.

### Example 4

### Siloxane Compound (D)

The synthesis was performed in the same manner as in Example 1, except for using 20.5 g (80 mmol) of (4-bromophenyl)phenylacetylene in place of 14.6 g (80.0 mmol) of 4-bromobenzocyclobutene. As a result, the silicon compound of the general formula (1) where X1=0; X2=8; R⁴, R⁵═CH₃; Y=cross-linking group of the structural formula (9); and n=2 (hereinafter referred to as “siloxane compound (D)”) was obtained in reddish-brown oily form in an amount of 25 g and at a yield of 83 mass %. The viscosity of this oily compound was 12000 mPa·s.

The structure and GPC measurement results of the siloxane compound (D) are indicated below.

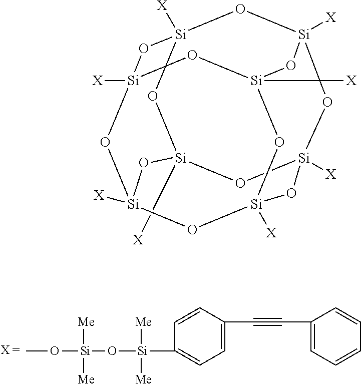

GPC (in terms of polystyrene, RI detector) Mw=2910, Mw/Mn=1.3.

This siloxane compound (D) was poured into a mold of silicon (product name “Shin-Etsu Silicon SH9555” manufactured by Shin-Etsu Chemical Co., Ltd.) and subjected to cross-linking reaction by heating at atmospheric pressure and at 350° C. for 1 hour, thereby forming a cured product of 2 mm thickness with no bubble and cracking. The 5 mass % reduction temperature of the cured product was 510° C.

[Comparison of Mass Reduction Rate]

The following siloxane compound described in Non-Patent Document 6 and falling out of the scope of the present invention was used as Comparative Example 1. The cross-linked cured products of the siloxane compounds (A) to (D) of Examples 1 to 4 and of the siloxane compound of Comparative Example 1 were measured and compared for their mass reduction rate. The measurement/comparison results are indicated in TABLE 1.

TABLE 1

| 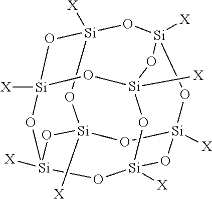 | | | |
|---|---|---|---|
| 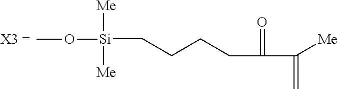 | | | |
| 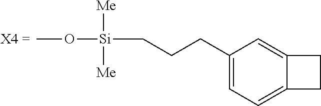 [SMILES: CO[Si](C)(C)CCCc1ccc2c(c1)CC2] | | | |
| (X3/X4 = 3/5) | | | |
| Comparative Example 1: Siloxane compound | | | |
| | Mass reduction rate (unit: mass %) | | |
| | 300° C. | 350° C. | 400° C. |
| Example 1 | 0.1 | 0.5 | 3.5 |
| Example 2 | 0.35 | 1.2 | 2.0 |
| Example 3 | 0.1 | 0.35 | 2.0 |
| Example 4 | 0.07 | 0.28 | 1.7 |
| Comparative | 1 or less | 18 | 30 |
| Example 1 | | | |

As is seen from TABLE 1, the cross-linked cured products of the siloxane compounds (A) to (D) of Examples 1 to 4 each had a smaller mass reduction rate at 300° C., 350° C. and 400° C. than the mass reduction rate of the cured product of Comparative Example 1. In other words, the cross-linked cured products of the siloxane compounds (A) to (D) of Examples 1 to 4 were higher in heat resistance than the cured product of Comparative Example 1.

Although the present invention has been described above with reference to the above specific exemplary embodiment, various modifications and variations of the embodiment described above can be made based on the common knowledge of those skilled in the art without departing from the scope of the present invention.

1. A siloxane compound of the general formula (1): 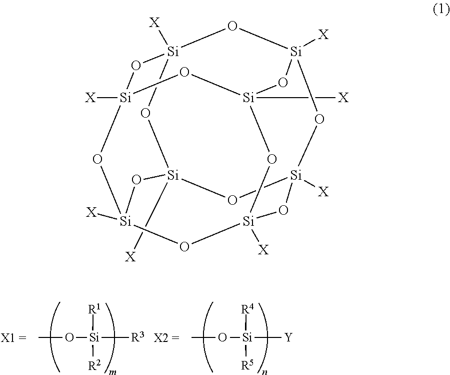
where X are each independently either X1 or X2 with the proviso that at least one of X is X2; R¹ to R⁵ are each independently a hydrogen atom, a C₁-C₈ alkyl, alkenyl or alkynyl group, a phenyl group or a pyridyl group; each of R¹ to R⁵ may have a carbon atom replaced by an oxygen atom and may have an ether bond, a carbonyl group or an ester bond in a structure thereof; m and n are each independently an integer of 1 to 10; and Y are each independently at least one cross-linking group selected from the group consisting of those of the structural formulas (2) to (12):

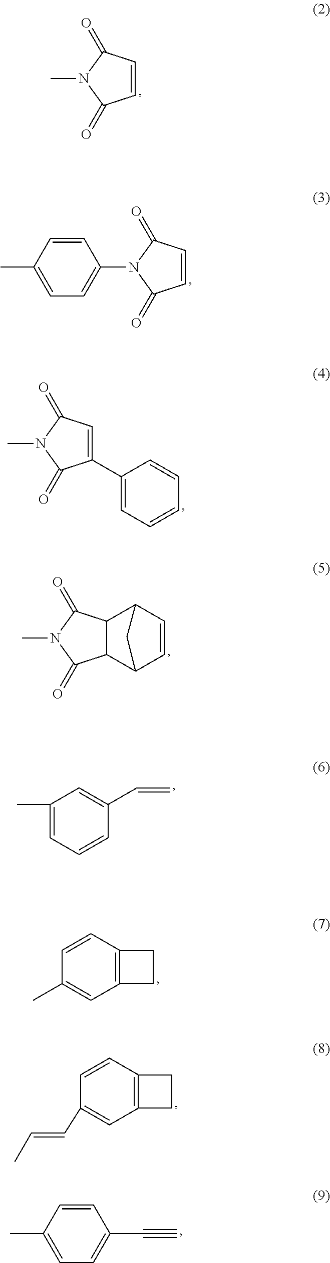

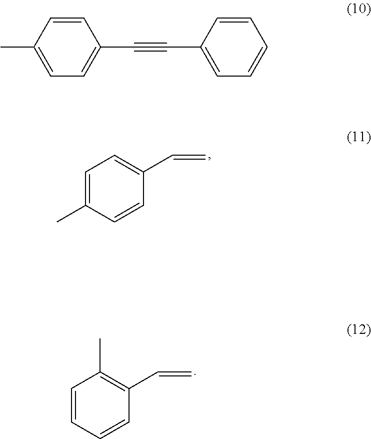

2. The siloxane compound according to claim 1, wherein all of R¹ to R⁵ are methyl, m is an integer of 1 to 3 and n is an integer of 2 to 3.

3. A cured product obtained by reaction of the cross-linking group of the siloxane compound according to claim 1.

4. A sealing material containing the cured product according to claim 3.
